(19) United States
(12) Patent Application Publication
(10) Pub. No.: US 2015/0130033 A1
(43) Pub. Date: May 14, 2015

(54) MODULE IC PACKAGE STRUCTURE WITH ELECTRICAL SHIELDING FUNCTION AND METHOD FOR MANUFACTURING THE SAME

(71) Applicant: AZUREWAVE TECHNOLOGIES, INC., New Taipei City (TW)

(72) Inventor: HUANG-CHAN CHIEN, NEW TAIPEI CITY (TW)

(73) Assignee: AZUREWAVE TECHNOLOGIES, INC., New Taipei City (TW)

(21) Appl. No.: 14/076,230

(22) Filed: Nov. 10, 2013

(51) Int. Cl. H01L 23/60; H01L 23/31; H01L 23/00

(52) U.S. Cl. CPC H01L 23/60; H01L 24/97; H01L 23/3114
USPC 257/659; 438/113

(57) ABSTRACT

A module IC package structure includes a substrate unit, an electronic unit, a package unit and a shielding unit. The substrate unit including a circuit substrate, a grounding layer disposed inside the circuit substrate, and an outer conductive structure disposed on the outer surrounding peripheral surface of the circuit substrate. The outer conductive structure includes a plurality of outer conductive layers. The grounding layer is exposed from the circuit substrate for directly contacting the outer conductive layers. The electronic unit includes a plurality of electronic components disposed on the circuit substrate. The package unit includes a package gel body disposed on the circuit substrate to enclose the electronic components. The shielding unit includes a metal shielding layer enclosing the package gel body and directly contacting the outer conductive structure. Whereby, the grounding layer is electrically connected to the metal shielding layer through the outer conductive structure directly.

### BACKGROUND OF THE INVENTION

1. Field of the Invention

The instant disclosure relates to a module IC (Integrated Circuit) package structure and a method for manufacturing thereof, and more particularly to a module IC package structure with electrical shielding function and a method for manufacturing thereof.

2. Description of Related Art

As integrated circuit technology has been rapidly developing, a variety of devices using the technology are developed continuously. Because the functions of the devices are rapidly added, most devices are implemented in a modular way. However, while the functions of the devices can be increased by integrating a lot of functional modules, the design of a multiple function device with small dimensions is still difficult.

In the semiconductor manufacturing process, a high level technology is used to manufacture a small chip or component. Therefore, the module manufacturer can design a functional module with small dimensions, and the device can be efficiently and fully developed. Currently, most modules use the printed circuit board (PCB), Flame Retardant 4 (FR-4), or Bismaleimide Triazine (BT) substrate as a carrier. All chips and components are mounted onto the surface of the carrier by using a surface mounting technology (SMT). Therefore, the substrate is merely used as a carrier and is used for connecting the circuit. The structure of the substrate is a multiple-layered structure and is only used for the circuit layout.

Following the development of radio frequency technology, wireless communication systems are becoming more powerful and their performance increases. Demands on these systems are low weight, small dimensions, high quality, low energy-consumption high reliability, and low manufacturing costs. Another important function of wireless communication systems is the electric shielding of radiation emitted by their components in order to minimize interference of this radiation with other electronic devices or components.

However, up to the present the production of the shielding structures adds disproportional costs and time expenditure to the total manufacturing costs. In many cases, the shielding structure is realized as a sheet steel casing around the wireless device or circuit module, necessitating the manufacture of costly dies for each shielding structure shape. Another currently employed method is to produce the casings by metal casting. In this case, each shape to be cast requires the manufacture of a specific casting mold which involves manual work, leading to high costs. Furthermore, the assembly of the metal casings and the circuit modules is usually performed manually thus further increases costs.

### SUMMARY OF THE INVENTION

One aspect of the instant disclosure relates to a module IC package structure with electrical shielding function and a method for manufacturing thereof.

One of the embodiments of the instant disclosure provides a module IC package structure with electrical shielding function, comprising: a substrate unit, an electronic unit, a package unit and a shielding unit. The substrate unit includes a circuit substrate having an outer surrounding peripheral surface, a grounding layer disposed inside the circuit substrate and enclosed by the circuit substrate, an outer conductive structure disposed on the outer surrounding peripheral surface of the circuit substrate, and an inner conductive structure disposed inside the circuit substrate and electrically connected between the grounding layer and the outer conductive structure, wherein the outer conductive structure includes a plurality of outer conductive layers disposed on the outer surrounding peripheral surface of the circuit substrate, the inner conductive structure includes a plurality of inner conductive layers respectively corresponding to the outer conductive layers, and each inner conductive layer has two opposite ends respectively contacting the grounding layer and the corresponding outer conductive layer. The electronic unit includes a plurality of electronic components disposed on the circuit substrate and electrically connected to the circuit substrate, wherein the electronic components are electrically connected to the grounding layer through the circuit substrate. The package unit includes a package gel body disposed on the circuit substrate to enclose the electronic components. The shielding unit includes a metal shielding layer disposed on the outer surface of the package gel body and directly contacting the outer conductive structure, wherein the grounding layer is electrically connected to the metal shielding layer through the inner conductive structure and the outer conductive structure in sequence.

More precisely, the outer conductive structure includes a plurality of half through holes disposed on the outer surrounding peripheral surface of the circuit substrate and passing through the circuit substrate, the outer conductive layers are respectively disposed on inner surfaces of the half through holes, and the half through holes are filled with the package gel body for covering the outer conductive layers. In addition, each outer conductive layer has two cutting lateral walls respectively disposed on two opposite end sides thereof, and each cutting lateral wall of each outer conductive layer is exposed from the circuit substrate and the package gel body for directly contacting the metal shielding layer.

Another one of the embodiments of the instant disclosure provides a module IC package structure with electrical shielding function, comprising: a substrate unit, an electronic unit, a package unit and a shielding unit. The substrate unit including a circuit substrate having an outer surrounding peripheral surface, a grounding layer disposed inside the circuit substrate, and an outer conductive structure disposed on the outer surrounding peripheral surface of the circuit substrate, wherein the outer conductive structure includes a plurality of outer conductive layers disposed on the outer surrounding peripheral surface of the circuit substrate, and the grounding layer is exposed from the outer surrounding peripheral surface of the circuit substrate for directly contacting the outer conductive layers. The electronic unit includes a plurality of electronic components disposed on the circuit substrate and electrically connected to the circuit substrate, wherein the electronic components are electrically connected to the grounding layer through the circuit substrate. The package unit includes a package gel body disposed on the circuit substrate to enclose the electronic components. The shielding unit includes a metal shielding layer disposed on the outer surface of the package gel body and directly contacting the outer conductive structure, wherein the grounding layer is electrically connected to the metal shielding layer through the outer conductive structure directly.

More precisely, the outer conductive structure includes a plurality of half through holes disposed on the outer surrounding peripheral surface of the circuit substrate and passing through the circuit substrate, the outer conductive layers are respectively disposed on inner surfaces of the half through holes, and the half through holes are filled with the package gel body for covering the outer conductive layers. In addition, each outer conductive layer has two cutting lateral walls respectively disposed on two opposite end sides thereof, and each cutting lateral wall of each outer conductive layer is exposed from the circuit substrate and the package gel body for directly contacting the metal shielding layer.

Yet another one of the embodiments of the instant disclosure provides a method for manufacturing a module IC package structure with electrical shielding function, comprising: providing an initial substrate including a plurality of substrate units connected with each other and arranged as a matrix, wherein each substrate unit includes a circuit substrate, a grounding layer disposed inside the circuit substrate, and an outer conductive structure electrically connected to the grounding layer; respectively placing a plurality of electronic units on the circuit substrates of the substrate units, wherein each electronic unit includes a plurality of electronic components disposed on the corresponding circuit substrate and electrically connected to the corresponding circuit substrate, and the electronic components of each electronic unit are electrically connected to the corresponding grounding layer through the corresponding circuit substrate; forming an initial package unit on the initial substrate to enclose the electronic units, wherein the initial package unit includes a plurality of package gel bodies connected with each other, and each package gel body is disposed on the corresponding circuit substrate to enclose the corresponding electronic components; cutting the initial substrate and the initial package unit for separating the substrate units from each other and the package gel bodies from each other, wherein the outer conductive structure of each substrate unit is exposed from the corresponding circuit substrate and the corresponding package gel body; and then forming a plurality of metal shielding layers, wherein each metal shielding layer is disposed on the outer surface of the corresponding package gel body, and each metal shielding layer directly contacts the outer conductive structure of the corresponding substrate unit.

More precisely, the grounding layer of the substrate unit is enclosed by the circuit substrate, the outer conductive structure of the substrate unit is disposed on an outer surrounding peripheral surface of the circuit substrate, and the substrate unit includes an inner conductive structure disposed inside the circuit substrate and electrically connected between the grounding layer and the outer conductive structure, wherein the outer conductive structure includes a plurality of outer conductive layers disposed on the outer surrounding peripheral surface of the circuit substrate, the inner conductive structure includes a plurality of inner conductive layers respectively corresponding to the outer conductive layers, and each inner conductive layer has two opposite ends respectively contacting the grounding layer and the corresponding outer conductive layer.

More precisely, the outer conductive structure of the substrate unit is disposed on an outer surrounding peripheral surface of the circuit substrate, the outer conductive structure includes a plurality of outer conductive layers disposed on the outer surrounding peripheral surface of the circuit substrate, and the grounding layer is exposed from the outer surrounding peripheral surface of the circuit substrate for directly contacting the outer conductive layers.

More precisely, the outer conductive structure includes a plurality of half through holes disposed on the outer surrounding peripheral surface of the circuit substrate and passing through the circuit substrate, the outer conductive layers are respectively disposed on inner surfaces of the half through holes, and the half through holes are filled with the package gel body for covering the outer conductive layers, wherein each outer conductive layer has two cutting lateral walls respectively disposed on two opposite end sides thereof, and each cutting lateral wall of each outer conductive layer is exposed from the circuit substrate and the package gel body for directly contacting the metal shielding layer.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a flowchart of the method for manufacturing a module IC package structure with electrical shielding function according to the first embodiment of the instant disclosure;

FIG. 2 shows a top, schematic view of the step S100 of the method for manufacturing a module IC package structure with electrical shielding function according to the first embodiment of the instant disclosure;

FIG. 3 shows a cross-sectional view taken along the section line A-A of FIG. 2;

FIG. 4 shows a cross-sectional, schematic view of the step S102 of the method for manufacturing a module IC package structure with electrical shielding function according to the first embodiment of the instant disclosure;

FIG. 5 shows a cross-sectional, schematic view of the step S104 of the method for manufacturing a module IC package structure with electrical shielding function according to the first embodiment of the instant disclosure;

FIG. 6 shows a top, schematic view of the step S106 of the method for manufacturing a module IC package structure with electrical shielding function according to the first embodiment of the instant disclosure;

FIG. 7 shows a cross-sectional, schematic view of the step S108 of the method for manufacturing a module IC package structure with electrical shielding function according to the first embodiment of the instant disclosure;

FIG. 8 shows a top, schematic view of the step S108 of the method for manufacturing a module IC package structure with electrical shielding function according to the first embodiment of the instant disclosure; and

FIG. 9 shows a cross-sectional, schematic view of the module IC package structure with electrical shielding function according to the second embodiment of the instant disclosure.

### DETAILED DESCRIPTION OF THE PREFERRED EMBODIMENTS

### First Embodiment

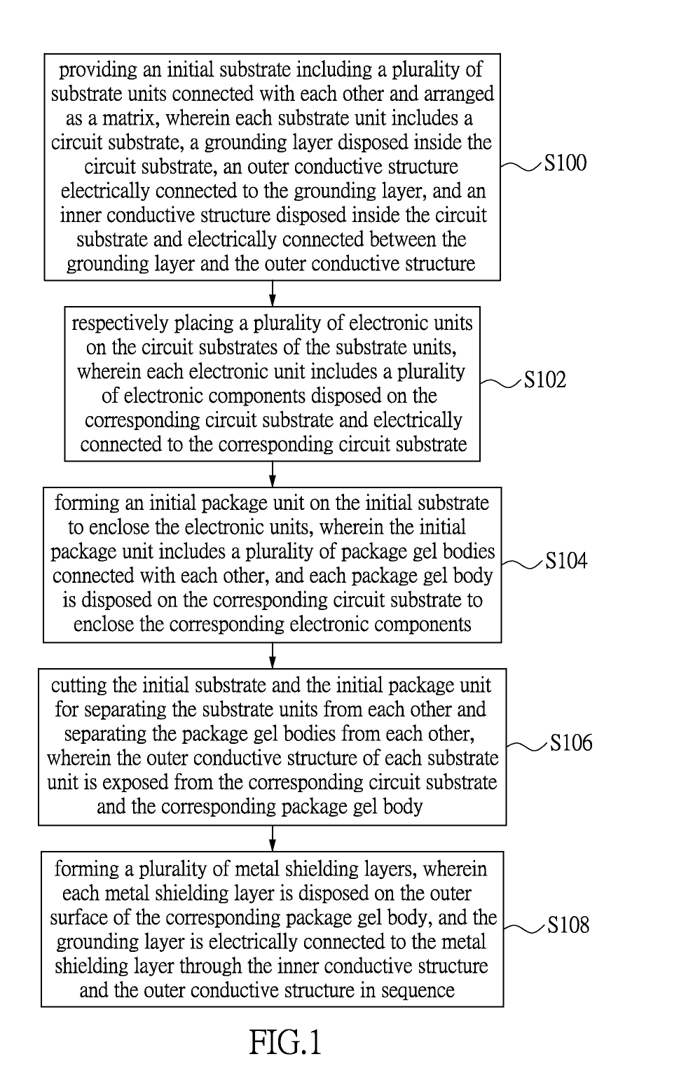

Referring to FIG. 1 to FIG. 7, the first embodiment of the instant disclosure provides a method for manufacturing a module IC package structure Z with electrical shielding function, comprising the following steps:

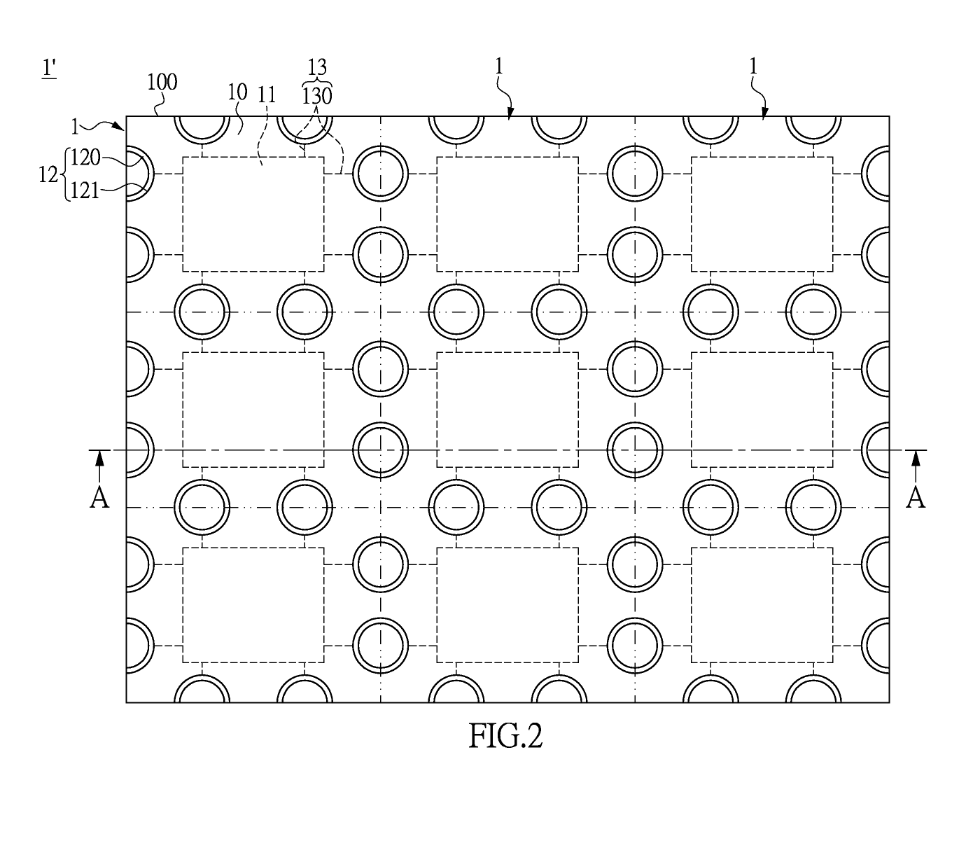

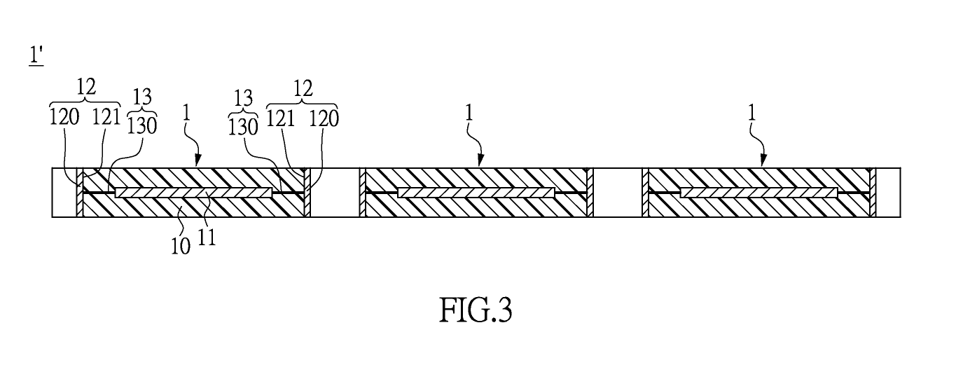

First, step S100 is that: referring to FIG. 1, FIG. 2 and FIG. 3, providing an initial substrate l′ including a plurality of substrate units 1 connected with each other and arranged as a matrix, wherein each substrate unit 1 includes a circuit substrate 10, a grounding layer 11 (such as a lamellar ground layer) disposed inside the circuit substrate 10, and an outer conductive structure 12 electrically connected to the grounding layer 11. For example, the substrate unit 1 may be a multilayer circuit board structure composed of many stacked layers, and the grounding layer 11 is one of the stacked layers of the multilayer circuit board structure. Thus, the grounding layer 11 may be a topmost layer of the multilayer circuit board structure, and the topmost layer is disposed on the top side of the circuit substrate 10, but it is merely an example and is not meant to limit the instant disclosure.

More precisely, the grounding layer 11 of the substrate unit 1 is enclosed by the circuit substrate 10, and the outer conductive structure 12 of the substrate unit 1 is disposed on an outer surrounding peripheral surface 100 of the circuit substrate 10. In addition, the outer conductive structure 12 includes a plurality of outer conductive layers 120 disposed on the outer surrounding peripheral surface 100 of the circuit substrate 10, the outer conductive structure 12 includes a plurality of half through holes 121 disposed on the outer surrounding peripheral surface 100 of the circuit substrate 10 and passing through the circuit substrate 10, and the outer conductive layers 120 are respectively disposed on inner surfaces of the half through holes 121. Moreover, the substrate unit 1 further includes an inner conductive structure 13 disposed inside the circuit substrate 10 and electrically connected between the grounding layer 11 and the outer conductive structure 12, the inner conductive structure 13 includes a plurality of inner conductive layers 130 (such as a strip conductive layer) respectively corresponding to the outer conductive layers 120, and each inner conductive layer 130 has two opposite ends respectively contacting the grounding layer 11 and the corresponding outer conductive layer 120.

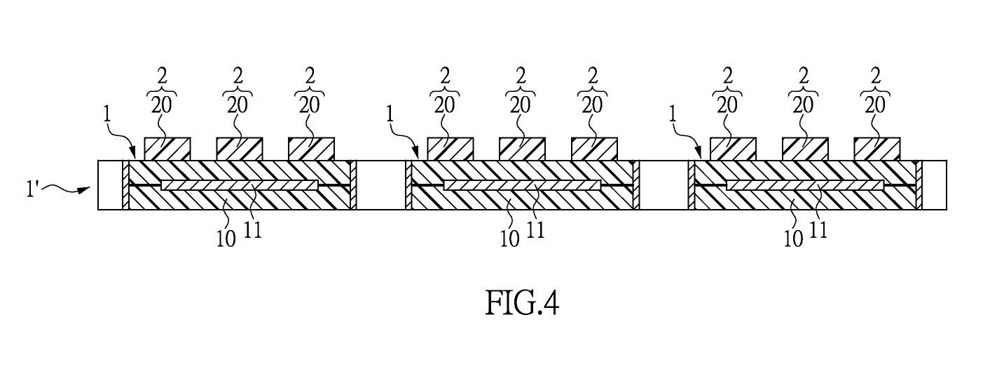

Then, step S102 is that: referring to FIG. 1, FIG. 3 and FIG. 4, respectively placing a plurality of electronic units 2 on the circuit substrates 10 of the substrate units 1. In addition, each electronic unit 2 includes a plurality of electronic components 20 (such as passive components or active components) disposed on the corresponding circuit substrate 10 and electrically connected to the corresponding circuit substrate 10, and the electronic components 20 of each electronic unit 2 are electrically connected to the corresponding grounding layer 11 through the corresponding circuit substrate 10. For example, the circuit substrate 10 as a multilayer circuit board structure includes at least one conductive structure disposed inside the circuit substrate 10 and electrically connected between the electronic component 20 and the grounding layer 11, thus the electronic components 20 of each electronic unit 2 can be electrically connected to the corresponding grounding layer 11 through the corresponding circuit substrate 10.

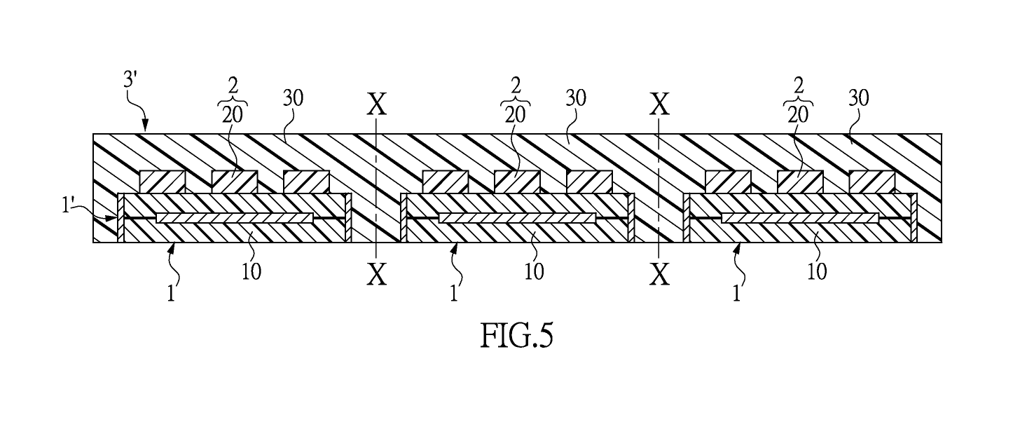

Next, step S104 is that: referring to FIG. 1, FIG. 4 and FIG. 5, forming an initial package unit 3′ on the initial substrate 1′ to enclose the electronic units 2. In addition, the initial package unit 3′ includes a plurality of package gel bodies 30 connected with each other, and each package gel body 30 is disposed on the corresponding circuit substrate 10 to enclose the corresponding electronic components 20. For example, the package gel body 30 may be an opaque resin body made of silicone or epoxy.

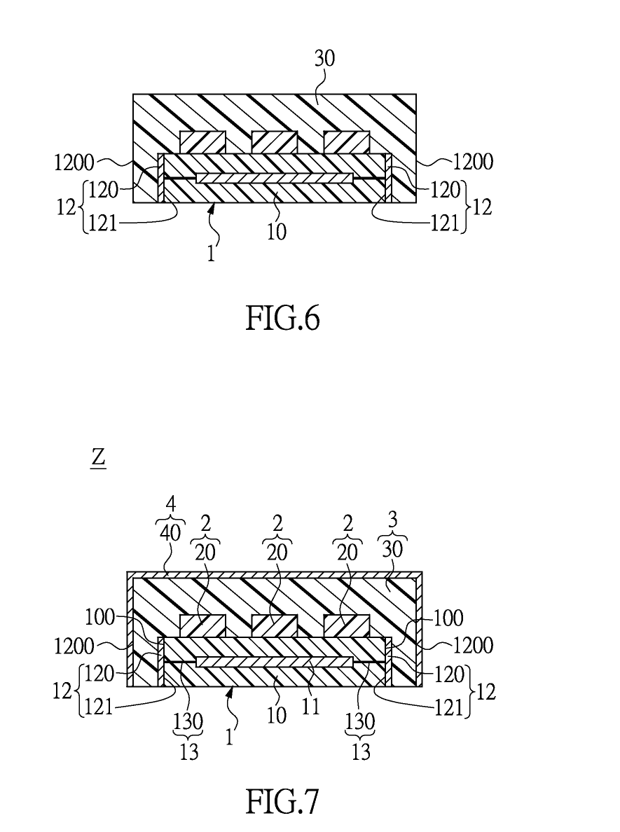

Subsequent, step S106 is that: referring to FIG. 1, FIG. 5 and FIG. 6, cutting the initial substrate 1′ and the initial package unit 3′ along the cutting line X-X as shown in FIG. 5 for separating the substrate units 1 from each other and separating the package gel bodies 30 from each other, wherein the outer conductive structure 12 of each substrate unit 1 is exposed from the corresponding circuit substrate 10 and the corresponding package gel body 30. More precisely, the half through holes 121 are filled with the package gel body 30 for covering the outer conductive layers 120. In addition, each outer conductive layer 120 has two cutting lateral walls 1200 respectively disposed on two opposite end sides thereof, and each cutting lateral wall 1200 of each outer conductive layer 120 is exposed from the circuit substrate 10 and the package gel body 30.

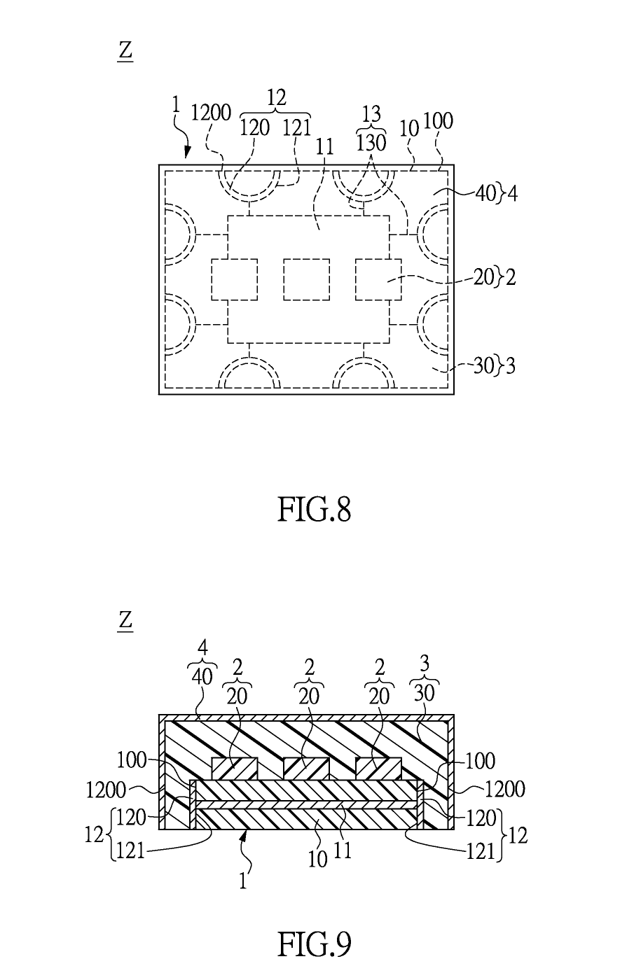

Finally, step S108 is that: referring to FIG. 1, FIG. 6, FIG. 7 and FIG. 8, forming a plurality of metal shielding layers 40, wherein each metal shielding layer 40 is disposed on the outer surface of the corresponding package gel body 30, and each metal shielding layer 40 directly contacts the outer conductive structure 12 of the corresponding substrate unit 1. Hence, the grounding layer 11 of each substrate unit 1 is electrically connected to the corresponding metal shielding layer 40 through the inner conductive structure 13 and the outer conductive structure 12 in sequence.

In conclusion, referring to FIG. 7 and FIG. 8, according to the above-mentioned manufacture method, the first embodiment of the instant disclosure provides a module IC package structure Z with electrical shielding function, comprising: a substrate unit 1, an electronic unit 2, a package unit 3 and a shielding unit 4.

First, the substrate unit 1 includes a circuit substrate 10 having an outer surrounding peripheral surface 100, a grounding layer 11 disposed inside the circuit substrate 10 and enclosed by the circuit substrate 10, an outer conductive structure 12 disposed on the outer surrounding peripheral surface 100 of the circuit substrate 10, and an inner conductive structure 13 disposed inside the circuit substrate 10 and electrically connected between the grounding layer 11 and the outer conductive structure 12. In addition, the outer conductive structure 12 includes a plurality of outer conductive layers 120 disposed on the outer surrounding peripheral surface 100 of the circuit substrate 10, the inner conductive structure 13 includes a plurality of inner conductive layers 130 respectively corresponding to the outer conductive layers 120, and each inner conductive layer 130 has two opposite ends respectively contacting the grounding layer 11 and the corresponding outer conductive layer 120.

Moreover, the electronic unit 2 includes a plurality of electronic components 20 disposed on the circuit substrate 10 and electrically connected to the circuit substrate 10, and the electronic components 20 are electrically connected to the grounding layer 11 through the circuit substrate 10. For example, the electronic component 20 may be may be a resistance, a capacitor, an inductance, a function chip having a predetermined function or a semiconductor chip having a predetermined function etc., but it is merely an example and is not meant to limit the instant disclosure.

Furthermore, the package unit 3 includes a package gel body 30 disposed on the circuit substrate 10 to enclose the electronic components 20, the shielding unit 4 includes a metal shielding layer 40 disposed on the outer surface of the package gel body 30 and directly contacting the outer conductive structure 12, and the package gel body 30 is enclosed by the metal shielding layer 40. Whereby, the grounding layer 11 is electrically connected to the metal shielding layer 40 through the inner conductive structure 13 and the outer conductive structure 12 in sequence. For example, the metal shielding layer 40 may be a conductive spray layer formed by spraying, a conductive sputtering layer formed by sputtering, a conductive printing layer formed by printing, or a conductive electroplating layer formed by electroplating etc., according to different requirements, but it is merely an example and is not meant to limit the instant disclosure.

More precisely, the outer conductive structure 12 includes a plurality of half through holes 121 disposed on the outer surrounding peripheral surface 100 of the circuit substrate 10 and passing through the circuit substrate 10, the outer conductive layers 120 are respectively disposed on inner surfaces of the half through holes 121, and the half through holes 121 are filled with the package gel body 30, thus the outer conductive layers 120 are enclosed by the package gel body 30.

### Second Embodiment

Referring to FIG. 9, the second embodiment of the instant disclosure provides a module IC package structure Z with electrical shielding function, comprising: a substrate unit 1, an electronic unit 2, a package unit 3 and a shielding unit 4. Comparing FIG. 9 with FIG. 7, the difference between the second embodiment and the first embodiment is as follows: in the second embodiment, the substrate unit 1 includes a circuit substrate 10 having an outer surrounding peripheral surface 100, a grounding layer 11 disposed inside the circuit substrate 10, and an outer conductive structure 12 disposed on the outer surrounding peripheral surface 100 of the circuit substrate 10. In addition, the outer conductive structure 12 includes a plurality of outer conductive layers 120 disposed on the outer surrounding peripheral surface 100 of the circuit substrate 10, and the terminal end of the grounding layer 11 is exposed from the outer surrounding peripheral surface 100 of the circuit substrate 10 (i.e., the terminal end of the grounding layer 11 is directly exposed from the half through holes 121 of the circuit substrate 10) for directly contacting the outer conductive layers 120, thus the grounding layer 11 is electrically connected to the metal shielding layer 40 through the outer conductive structure 12 directly.

In conclusion, referring to FIG. 7, as shown in the first embodiment, the grounding layer 11 is electrically connected to the metal shielding layer 40 through the inner conductive structure 13 and the outer conductive structure 12 in sequence. However, referring to FIG. 9, as shown in the second embodiment, the grounding layer 11 is electrically connected to the metal shielding layer 40 through the outer conductive structure 12 directly.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

1. A module IC package structure with electrical shielding function, comprising:
a substrate unit including a circuit substrate having an outer surrounding peripheral surface, a grounding layer disposed inside the circuit substrate and enclosed by the circuit substrate, an outer conductive structure disposed on the outer surrounding peripheral surface of the circuit substrate, and an inner conductive structure disposed inside the circuit substrate and electrically connected between the grounding layer and the outer conductive structure, wherein the outer conductive structure includes a plurality of outer conductive layers disposed on the outer surrounding peripheral surface of the circuit substrate, the inner conductive structure includes a plurality of inner conductive layers respectively corresponding to the outer conductive layers, and each inner conductive layer has two opposite ends respectively contacting the grounding layer and the corresponding outer conductive layer;
an electronic unit including a plurality of electronic components disposed on the circuit substrate and electrically connected to the circuit substrate, wherein the electronic components are electrically connected to the grounding layer through the circuit substrate;
a package unit including a package gel body disposed on the circuit substrate to enclose the electronic components; and
a shielding unit including a metal shielding layer disposed on the outer surface of the package gel body and directly contacting the outer conductive structure, wherein the grounding layer is electrically connected to the metal shielding layer through the inner conductive structure and the outer conductive structure in sequence;
wherein the outer conductive structure includes a plurality of half through holes disposed on the outer surrounding peripheral surface of the circuit substrate and passing through the circuit substrate, the outer conductive layers are respectively disposed on inner surfaces of the half through holes, and the half through holes are filled with the package gel body for covering the outer conductive layers.

2. (canceled)

3. The module IC package structure of claim 1, wherein each outer conductive layer has two cutting lateral walls respectively disposed on two opposite end sides thereof, and each cutting lateral wall of each outer conductive layer is exposed from the circuit substrate and the package gel body for directly contacting the metal shielding layer.

4. A module IC package structure with electrical shielding function, comprising:
a substrate unit including a circuit substrate having an outer surrounding peripheral surface, a grounding layer disposed inside the circuit substrate, and an outer conductive structure disposed on the outer surrounding peripheral surface of the circuit substrate, wherein the outer conductive structure includes a plurality of outer conductive layers disposed on the outer surrounding peripheral surface of the circuit substrate, and the grounding layer is exposed from the outer surrounding peripheral surface of the circuit substrate for directly contacting the outer conductive layers;
an electronic unit including a plurality of electronic components disposed on the circuit substrate and electrically connected to the circuit substrate, wherein the electronic components are electrically connected to the grounding layer through the circuit substrate;
a package unit including a package gel body disposed on the circuit substrate to enclose the electronic components; and
a shielding unit including a metal shielding layer disposed on the outer surface of the package gel body and directly contacting the outer conductive structure, wherein the grounding layer is electrically connected to the metal shielding layer through the outer conductive structure directly;
wherein the outer conductive structure includes a plurality of half through holes disposed on the outer surrounding peripheral surface of the circuit substrate and passing through the circuit substrate, the outer conductive layers are respectively disposed on inner surfaces of the half through holes, and the half through holes are filled with the package gel body for covering the outer conductive layers.

5. (canceled)

6. The module IC package structure of claim 4, wherein each outer conductive layer has two cutting lateral walls respectively disposed on two opposite end sides thereof, and each cutting lateral wall of each outer conductive layer is exposed from the circuit substrate and the package gel body for directly contacting the metal shielding layer.

7. A method for manufacturing a module IC package structure with electrical shielding function, comprising:
providing an initial substrate including a plurality of substrate units connected with each other and arranged as a matrix, wherein each substrate unit includes a circuit substrate, a grounding layer disposed inside the circuit substrate, and an outer conductive structure electrically connected to the grounding layer;
respectively placing a plurality of electronic units on the circuit substrates of the substrate units, wherein each electronic unit includes a plurality of electronic components disposed on the corresponding circuit substrate and electrically connected to the corresponding circuit substrate, and the electronic components of each electronic unit are electrically connected to the corresponding grounding layer through the corresponding circuit substrate;
forming an initial package unit on the initial substrate to enclose the electronic units, wherein the initial package unit includes a plurality of package gel bodies connected with each other, and each package gel body is disposed on the corresponding circuit substrate to enclose the corresponding electronic components;
cutting the initial substrate and the initial package unit for separating the substrate units from each other and the package gel bodies from each other, wherein the outer conductive structure of each substrate unit is exposed from the corresponding circuit substrate and the corresponding package gel body; and
forming a plurality of metal shielding layers, wherein each metal shielding layer is disposed on the outer surface of the corresponding package gel body, and each metal shielding layer directly contacts the outer conductive structure of the corresponding substrate unit;
wherein the outer conductive structure of the substrate unit is disposed on an outer surrounding peripheral surface of the circuit substrate, the outer conductive structure includes a plurality of outer conductive layers disposed on the outer surrounding peripheral surface of the circuit substrate, the outer conductive structure includes a plurality of half through holes disposed on the outer surrounding peripheral surface of the circuit substrate and passing through the circuit substrate, the outer conductive layers are respectively disposed on inner surfaces of the half through holes, and the half through holes are filled with the package gel body for covering the outer conductive layers.

8. The method of claim 7, wherein the grounding layer of the substrate unit is enclosed by the circuit substrate, the substrate unit includes an inner conductive structure disposed inside the circuit substrate and electrically connected between the grounding layer and the outer conductive structure, the inner conductive structure includes a plurality of inner conductive layers respectively corresponding to the outer conductive layers, and each inner conductive layer has two opposite ends respectively contacting the grounding layer and the corresponding outer conductive layer.

9. The method of claim 7, wherein the grounding layer is exposed from the outer surrounding peripheral surface of the circuit substrate for directly contacting the outer conductive layers.

10. The method of claim 9, wherein each outer conductive layer has two cutting lateral walls respectively disposed on two opposite end sides thereof, and each cutting lateral wall of each outer conductive layer is exposed from the circuit substrate and the package gel body for directly contacting the metal shielding layer.
